(19) United States
(12) Patent Application Publication
(10) Pub. No.: US 2004/0085723 A1
(43) Pub. Date: May 6, 2004

(54) Optical disk storage method and apparatus

(76) Inventor: Steven F. Hartung, Boulder, CO (US)

Correspondence Address: LATHROP & GAGE LC, 4845 PEARL EAST CIRCLE, SUITE 300, BOULDER, CO, 80301, US

(21) Appl. No.: 10/695,962

(22) Filed: Oct. 28, 2003

Related U.S. Application Data
(60) Provisional application No. 60/421,728, filed on Oct. 28, 2002.
(60) Provisional application No. 60/449,948, filed on Feb. 25, 2003.

(51) Int. Cl. G06F 12/00; H05K 5/00

(52) U.S. Cl. 361/684; 711/112; 711/163

(57) ABSTRACT

Systems and methods relating to a cartridge containing a stack of rewritable optical data storage media platters and a mechanism used to store and retrieve data from the cartridge where all platters in the cartridge are used as a single data volume. The cartridge is locked to substantially preclude human access to the media platters. A cartridge door is opened by the drive mechanism when the cartridge is inserted. An extraction assembly may extract one or more platters from the cartridge for loading into the drive mechanism. An elevator assembly may vertically align the drive mechanism with the extracted platters. Where multiple platters are selected, the drive mechanism may include multiple read/write assemblies to simultaneously read or write from multiple platters. Where multiple platters are used, striping techniques may be applied to enhance data bandwidth performance. Additional error-checking and/or redundancy information may be written to the platters to enhance reliability.

### RELATED PATENTS

This application claims the benefit of U.S. Provisional Application No. 60/421,728 filed Oct. 28, 2002, entitled Optical Disk Storage Method and Apparatus, which is expressly incorporated herein by reference. This application claims the benefit of U.S. Provisional Application No. 60/449,948 filed Feb. 25, 2003, entitled Optical Disk Storage Method and Apparatus, which is expressly incorporated herein by reference.

### BACKGROUND OF THE INVENTION

1. Field of the Invention

The invention relates to storage systems and more specifically, relates to an optical media cartridge providing high capacity and flexible applications.

2. Discussion of Related Art

Large computing systems use large mass storage subsystems having significant storage capacities. Such computing enterprises have similarly large needs for backup storage systems to archive and backup the significant storage capacity of the mass storage subsystem.

Magnetic tape media have long been the media of choice for backup and archive of such mass storage subsystems. As compared to rotating magnetic disk media, magnetic tape media traditionally offer a substantially lower cost per byte and due to their removable nature may be easily transported off-site for improved reliability in case of disaster.

In the current state of the art, optical media, such as DVD RW, have received limited acceptance in such large data center applications. Though optical media offer advantages of cost and storage life over magnetic recording media such as magnetic tape, they lack the level of capacity, reliability, and bandwidth (data read/write rate) required for professional data center backup and archiving.

It is evident from the above discussions that a need exists for improved structures and methods to utilize optical media for backup and archival applications.

### SUMMARY OF THE INVENTION

The present invention solves the above and other problems, thereby advancing the state of the useful arts, by providing system and associated methods for applying multiple optical disk media organized in a cartridge in conjunction with a read/write device such that data bandwidth and reliability are enhanced. In one aspect hereof, a media cartridge is loaded with a stack of disks organized into interleaved groups of disks. The interleaved structure (also referred to as “striped”) enhances data bandwidth by using multiple read/write components to access multiple storage surfaces simultaneously. In another aspect hereof, the data on each disk surface in the cartridge is formatted with redundancy information to enhance reliability of the data stored in the cartridge. In yet another aspect hereof, the data is formatted with meta-data to enable emulation of tape device commands and protocols. Another aspect hereof provides a read/write drive assembly that is constructed to access the interleaved sets of disks to read and write data to the cartridge. The drive presents all of the groups sequentially as one large storage volume to the host system.

By using multiple disk platters, the cartridge provides the user with a much larger storage capacity than provided by a single disk system as presently practiced. By using several read/write mechanisms in parallel and striping the data, the data rate is a multiple of what can be achieved on a single disk. By using error correction coding or other redundancy information, reliability is increased beyond what can be achieved on a single disk. By encasing the media in a cartridge that keeps contaminants and ultra-violet radiation away from the disks the storage life and data reliability are further enhanced.

Tradeoffs in cost, size, and performance may be tuned to market needs by scaling the number of disks in the cartridge (capacity vs. size and cost) or the number of read/write mechanisms in the drive assembly (data rate and reliability vs. cost and size). Further, the cartridge may be adapted to utilize numerous form factors of optical media having different storage density attributes and size attributes.

For example, using DVD RW media platters, a cartridge and drive system can be constructed that is suitable for backup, archiving, and near-line storage. DVD single platter drives do not have the throughput or capacity to fill the needs of large data centers. Increases in magnetic recording densities and data rates will continue to out pace single disk optical media for some time. Data rate, reliability, and unit capacity can all be addressed using DVD RW disks stacked in a cartridge (or any other rewritable optical media such as CD-RW, mini disks, or future formats such as holographic disks). The multiple disks provide a larger total capacity while packaging the platters in a single cartridge simplifies user handling to that of a single unit.

By adding RAID striping techniques and a logical format that is recorded into the physical DVD blocks, the system can emulate any kind of standard storage device—disk, tape, or even a super large CD/DVD disc. For the tape model, the analogy can be extended to treating each disc as if it were a physical tape track.

The data is buffered and optionally compressed using software or hardware data compression built into the unit. A mechanism and controlling electronics moves disks from the cartridge to a stack of DVD RW mechanisms.

The DVD RW mechanisms can be made out of standard high volume DVD components, or even whole low-profile drives made for portable computing applications. The DVD RW mechanisms are attached at fixed intervals to a common elevator mechanism that raises or lowers them all as a single unit. The fixed interval spacing of the RW drive mechanisms lines up with an even multiple of the disks in the cartridge such that in each loading position of the elevator, a set of disks will line up with the complete set of drives. The cartridge contains disks stacked closely together to maximize the capacity per unit volume. Because optical read/write mechanisms cannot be fit between the platters when they are so tightly packed into the cartridge, the drive mechanism must extract the disks to access them. The device has a mechanism for extracting the disk sets from the cartridge and returning them when they are no longer needed.

The cartridge is a plastic shell that holds the discs in a vertical stack as tightly as possible while still providing a mechanism of separation to keep the discs from touching each other and getting scratched. The cartridge has a door that has a locking mechanism that is open by the drive when the cartridge is inserted. The door latch is intended to by opened by the drive, but not to be easily opened by the user when the cartridge is out of the drive. Encasing the disks in an opaque cartridge that eliminates exposure to UV radiation also extends data storage life. The disks are installed in the cartridge during manufacturing and are not intended for individual removal or replacement by the end user. This invention differs from the common concept of a disk magazine in that the user never handles individual disks at any time, and that individual disks only contain an incomplete part of the data that makes up the total media volume that is represented by the cartridge. The unit of storage is the entire cartridge and the internal disks are merely a component that can only be accessed by the proper drive mechanism. The disks are formatted such that they are only usable when accessed in their properly ordered sets.

### BRIEF DESCRIPTION OF THE DRAWINGS

FIG. 1 is a block diagram of an exemplary storage system embodying features and aspects hereof.

FIG. 2 depicts one embodiment of a cartridge with extraction features in accordance with features and aspects hereof.

FIG. 3 depicts one embodiment of a cartridge in accordance with features and aspects hereof with an open door and a full load of optical media platters.

FIG. 4 depicts one embodiment of a cartridge in accordance with features and aspects hereof with a subset of three platters extracted for access.

FIG. 5 is a top view of cartridge inserted in drive mechanism in accordance with features and aspects hereof with a subset of platters extracted for access by the drive mechanism

FIG. 6 is a perspective view of cartridge inserted in drive mechanism in accordance with features and aspects hereof with a subset of three platters extracted for access by the drive mechanism.

FIG. 7 is a block diagram of a cartridge in a drive mechanism coupled to a host system in accordance with features and aspects hereof.

FIG. 8 is a block diagram showing an exemplary embodiment of functional elements and their interconnection with mechanisms in accordance with features and aspects hereof.

FIG. 9 is a flowchart describing exemplary command flow in accordance with features and aspects hereof.

FIG. 10 is a flowchart describing additional details of a media write command flow in accordance with features and aspects hereof.

FIG. 11 is a flowchart describing additional details of a media read command flow in accordance with features and aspects hereof.

FIG. 12 is a flowchart describing additional details of a media seek command flow in accordance with features and aspects hereof.

FIG. 13 is a flowchart describing additional details of media subset load and unload methods in accordance with features and aspects hereof.

FIG. 14 is a block diagram showing an exemplary mapping of blocks on a plurality of platters to provide enhanced performance and reliability in accordance with features and aspects hereof.

FIG. 15 is a block diagram showing an exemplary mapping of blocks on a plurality of platters to provide enhanced performance and reliability in accordance with features and aspects hereof.

### DETAILED DESCRIPTION OF THE DRAWINGS

FIG. 7 shows a system 700 embodying features and aspects hereof A multi-disk drive mechanism 702 is adapted to receive a cartridge 704 to manipulate multiple optical media platters within the cartridge 704. The drive mechanism may be coupled to a host system 706 via an appropriate interface bus 708. Interface bus 708 may be any of several well known communication media and protocols useful to couple peripheral devices, such as storage devices, to a host computer system or a network of such systems. Host system 706 may be a standard personal computer or workstation, a large “mainframe” computer system, or may represent an entire network of any mix of computer systems. Those of ordinary skill in the art will readily recognize a variety of other host system configurations that may advantageously utilize the features and aspects hereof shown in FIG. 7.

As discussed further herein below, drive 702 may also include robotic manipulation components (not shown) that extract a subset of the plurality of media platters from the cartridge 704 when the cartridge 704 is inserted in the drive 702. Drive 702 may also include components that move the drive mechanism and extracted platters relative to one another to provide alignment required to access data stored on the subset of extracted platters.

As an example, the cartridge 704 may contain 12 disks stacked close enough together to make the cartridge a convenient size to handle and of an appropriate size to fit in a standard computer form-factor drive. The multiple platters are preferably stacked closely to reduce the total height of the cartridge. Drive 702 may include one or more read/write mechanisms to access the surfaces of the platters in the cartridge 704. However, 12 optical read/write mechanisms cannot fit between the platters when they are so tightly packed into the cartridge 704. The drive mechanism 702 must extract the disks to access them. For example, the drive may have three read/write mechanisms and extracts every fourth disk at one time—i.e., a “subset” of the platters. The data may then be written or read onto or from three disks at a time. In one aspect hereof, where multiple platters are accessed as a subset, the data read or written on the subset is “striped” to improve the performance of the storage system. In order to extract the desired subset of platters, the drive mechanism 702 performs required vertical alignment to align the read/write head assembly with the subset of platters. An extraction element then extracts the desired subset from the cartridge 704 and engages the subset with the read/write head assembly of the drive mechanism 702. When done accessing the disk subset, the subset of disks are returned to the cartridge and the vertical position of the read/write heads are free to be re-aligned for a next subset of platters.

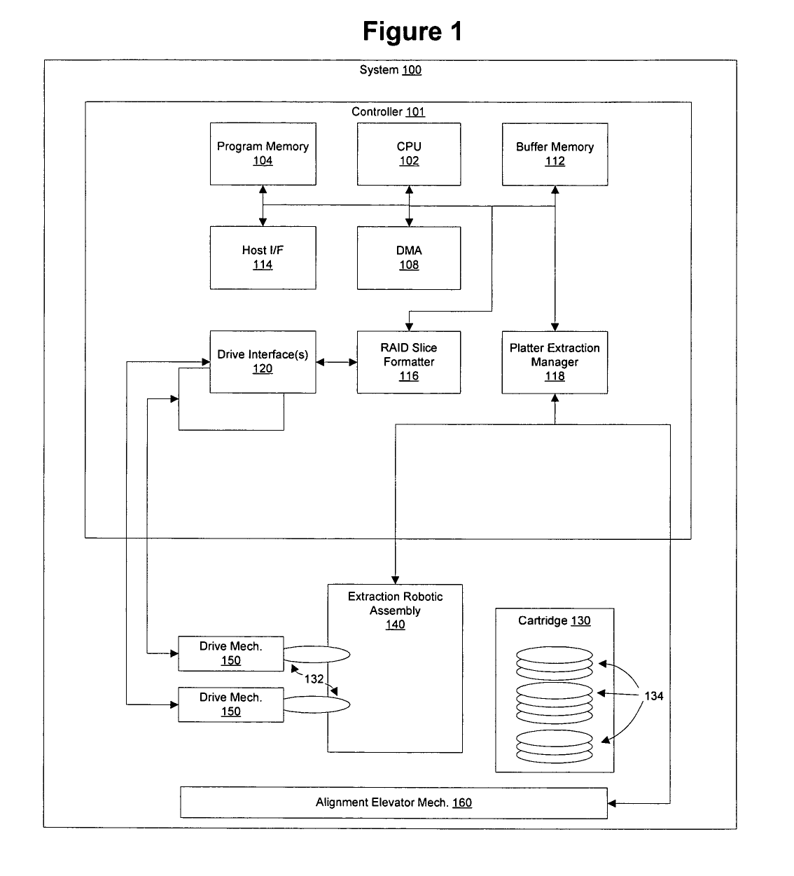

FIG. 1 is a block diagram showing additional details of an exemplary embodiment of a system 100 providing features and aspects hereof. Controller 101 provides overall control of the system 100 and interface communications with attached host systems. Controller 101 may include processor 102 suitably programmed to provide control and communications features and aspects hereof. Program instructions and data may be stored and fetched from program memory 104. Buffer memory 112 may be used by processor 102 to temporarily buffer and stage data exchanged between the hosts and the storage devices. DMA 108 provide enhanced data transfer capabilities for processor 102 between the various components of controller 101.

Host interface 114 provides host connectivity to one or more host systems and/or networks of host systems. As noted, host interface 114 may provide communications over any of numerous well known media and protocols. Examples of such media and protocols may include SCSI, iSCSI, IEEE-1394, ATA or S-ATA, Fibre Channel, Serial Attached SCSI, IDE, ATAPI, Ethernet, and any of numerous other similar interfaces.

RAID slice formatter 116 provides optional RAID striping an/or parity generation for data stored on, and retrieved from, the storage devices. As noted above, systems in accordance with features hereof may use a single platter extracted from the cartridge as a subset as well as multiple platters in a subset extracted from the cartridge. Where multiple platters are extracted as a subset, features and aspects hereof may stripe data over the multiple platters of the subset to enhance performance as well as generate redundancy information to further improve reliability. When multiple disks in a subset are simultaneously accessed, the system provides the enhanced throughput at acceptable data rates. Further, using multiple disks in parallel, the system can stripe data across many disks at once and use ECC redundancy techniques for increased data reliability analogous to RAID systems applied in hard disk drives. Such RAID management features of system 100 may be provided by RAID slice formatter 116 to manage distribution/mapping of slices or stripes of related blocks of data distributed over multiple platters along with redundancy information associated with each stripe or slice. Whether striped or not, drive interfaces 120 provide interfacing between controller 101 and one or more drive mechanisms 150. The interface between the controller 101 and the drive mechanisms 150 via interfaces 120 may utilize IDE, SCSI or numerous other well known interface media and protocols for communication between such storage devices and the controller, or may be an internal DMA bus (as a matter of hardware implementation design choice).

Cartridge 130 contains a plurality of optical media platters 134 densely packaged within. A cover (not shown) is normally closed to substantially preclude user access to the cartridges within. The cover is opened by interlocking mechanisms (not shown) within system 100 when the cartridge is inserted into the system.

Extraction robotic assembly 140 includes robotic gripper and manipulator elements controlled by platter extraction manager 118 of controller 101. Extraction assembly 140 extracts one or more platters 132 from the plurality of platters 134 within cartridge 130. The extracted platter/platters 132 are then mounted on drive mechanisms 150 for reading or writing of data and then returned to cartridge 130 by extraction assembly 140. Elevator mechanism 160 is also controlled by platter extraction manager 118 to provide vertical alignment of extracted platters 132 with drive mechanisms 150 and/or with cartridge 130 when moved therebetween by extraction assembly 140. In particular, elevator mechanism 160 provides robotic manipulation to align extraction assembly 140 with cartridges 130 and with drive mechanisms 150 when platters 132 are inserted or retracted from either drive mechanisms 150 or cartridge 130. Such robotic manipulators, grippers, actuators and sensors are generally known to those of ordinary skill in the arts as exemplified by issued U.S. Pat. Nos. 6,424,111, 5,892,750, 5,867,458, 5,815,340, 5,661,287, and 5,622,470, all of which are hereby incorporated by reference.

A command is initiated by the host computer and sent to the device target using standard command protocols (i.e. SCSI or SCSI-like in the case of ATAPI, etc.). The command set can mimic almost any existing block level devices, depending on the best market for the device attachment. Mimicking a tape drive would allow use of existing backup and archiving software applications and infrastructure. Mimicking a CD-RW command set would allow random access to the drives.

In an example embodiment, the target SCSI interface exists on a PCB that serves as a back plane for the low-cost ATA/ATAPI DVD RW mechanisms that are used to read and write the data to disk. During write operations, the back plane, which I will call the controller from this point forward, will buffer and/or compress the data when emulating a tape device. The controller will move the drive mechanisms in sets that are at fixed distances from each other in order to align them with the corresponding set of disks that will makeup the virtual track. After loading and verifying the appropriate disk set is in the drives, the controller will stripe the buffered data and generate ECC before writing to the disks. Ideally three read/write mechanisms or more are used, thus allowing a level of redundancy and striping for very high data integrity, analogous to RAID 5. If physical space limitations restrict the unit to only two read/write mechanisms, data integrity will not be tolerant of an entire disk loss, but will still be very much improved for individual block errors by using ECC appended to the logical data blocks.

For the read process the path is reversed. The mechanism positions to load the proper disk set and the disk loads and is verified by reading header information near the beginning of the disk. The requested data is then read from all the disks in the set in parallel. The individual stripes of data from the separate disks in the set are then recombined into the original user data, applying ECC as necessary to correct for errors. When complete, the data is transmitted to the host computer via the host peripheral interface that originated the command.

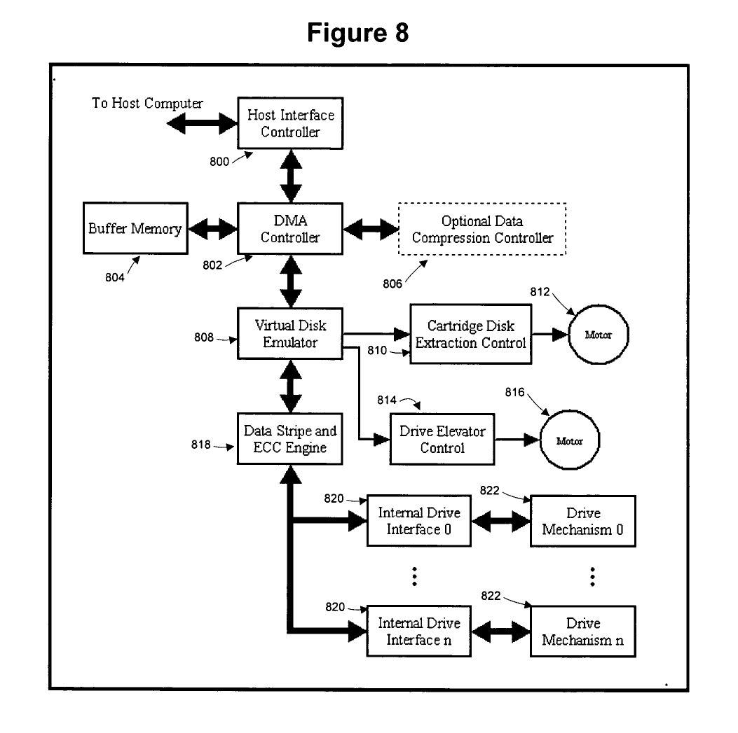

FIG. 8 shows a diagram of the major functional elements and their interconnection with mechanisms in the drive assembly that receives a cartridge of multiple platters. Those of ordinary skill in the art will recognize that these functional blocks may be implemented through the use of logic circuits or through software control of a microprocessor as a matter of design choice. Further, those of ordinary skill in the art will recognize a variety of equivalent functional descriptions and decompositions of these and other functional elements. FIG. 8 is therefore merely intended as representative of one possible such functional decomposition.

Host interface controller 800 interacts with an attached host system to exchange commands, status and data for storing and retrieving data on the multiple platters of a cartridge. Data, commands and status so exchanged may be forwarded to (or received from DMA controller 802. As known in the art, DMA controller 802 provides for reduction of processing overhead on an associated general or special purpose processor. Data to be exchanged may be stored in buffer memory 804 accessed through DMA controller 802. In addition, optionally, data stored or retrieved from buffer memory 804 or otherwise exchanged through the system may be compressed and decompressed by data compression controller 806 coupled to DMA controller 802. Commands, status and corresponding data to be exchanged with the host may then be processed by virtual disk emulator 808. Emulator 808 (also referred to herein as a virtualization engine) provides capabilities for the system to emulate various types of devices. By emulating SCSI Stream Command (SSC) the system may emulate the functions of a streaming tape drive. By emulating SCSI Multimedia Command (MMC), the system may emulate the functions of a multi-media device. Specifications for these and other standard command sets are known to those skilled in the art and are readily at, for example, http://www.t10.org.

Emulator 808 translates received commands, status and data as appropriate to manipulate the extraction assembly and the elevator assembly for purposes of extracting one or more platters from the cartridge and to align the read/write assemblies as appropriate to process the extracted platters. Emulator 808 therefore interacts with extraction control 810 that, in turn, controls motor 812 as required to extract required platters. Emulator 808 also interacts with elevator control 814 that, in turn, controls motor 816 to properly position the read/write assemblies to read or write data on the extracted platters.

Data stripe and ECC engine 818 then processes the data to be read from, or written to, the extracted platters. The data may be distributed to provide striping as noted above. Striping provides performance enhancement over that achieve by a single media drive mechanism. Engine 818 may also provide additional redundancy or error checking information to be recorded with the data to enhance reliability beyond that provided by a single media drive mechanism. Engine 818 may therefore provide full RAID management over a plurality of platters or may simply provide striping of data or may simply provide additional ECC or other error-checking codes when the data is written to the platters. Conversely, when data is read from the platters, engine 818 may utilize the striping, RAID redundancy data and/or error checking codes provided earlier to improve performance and reliability of read data from the cartridge system hereof. Engine 818 therefore interacts with the drive interface elements 820 that, in turn, control the drive mechanisms 822.

Operation: Cartridge and Disk Handling

The above identified functional and structural elements are operable to handle an inserted cartridge to read and write data on the surfaces of the multiple platters contained in the cartridge.

The platters are not intended to be individually accessible. Rather, they are locked in the cartridge case and are only extractable by the mechanism. The cartridge is inserted in the drive as a closed unit. When inserted into the drive a door is opened on the cartridge allowing access to the stack of platters. A slidable tray, pull-tab or other mechanical extraction means is associated with each platter. The drive mechanism aligns vertically with the desired platter/platters and engages the extraction means to initiate extraction of the platter/platters into the drive mechanism. The platters may be extracted while the drive read/write mechanisms are positioned just below each extracted platter of the cartridge. Once the extracted platters are in place, the drive elevator will raise sufficiently to engage the platters in the drives and separate them from the cartridge extraction mechanism so that they can spin. The disk platters may be fully extracted completely outside the cartridge, or may remain with a portion of the platter still inside the cartridge case outline (thus reducing the overall depth requirement of the drive assembly). In one aspect hereof, approximately 1/3 of the media platter may remain within the cartridge. Any portion of the platter may remain in the cartridge to reduce the depth of the system so long as enough of the media is exposed to properly engage with the drive mechanism.

Disk platters may be extracted in subsets (one or more at a time) according to the redundancy level of drive mechanisms being used. Where striping or full RAID level 5 management techniques are utilized, a subset may comprises multiple platters.

A platter is always mated to a specific subset and a specific drive mechanism. In an example, platters may be numbered sequentially from ‘0’ starting at the bottom of the cartridge and counting up; drive mechanisms may be identified sequentially starting with ‘A’ and increasing from the bottom of the mechanism. The individual drive mechanisms may be thought of as channels to record or read data through. Table 3 below illustrates an example of a two-read/write mechanism using a 12-platter cartridge:

TABLE 3
Disk Mapping in 2 Channel Unit

| | Logical Disk Set Number | |
|---|---|---|
| | (or virtual track or RAID | Read/write |
| Platter Number | Set) | Mechanism |
| 0 | 1 | A |
| 1 | 2 | A |
| 2 | 3 | A |
| 3 | 4 | A |
| 4 | 5 | A |
| 5 | 6 | A |
| 6 | 1 | B |
| 7 | 2 | B |
| 8 | 3 | B |
| 9 | 4 | B |
| 10 | 5 | B |
| 11 | 6 | B |

Table 4 below illustrates an example of a three-read/write mechanism using a 12-platter cartridge:

TABLE 4
Disk Mapping in 3 Channel Unit

| | Logical Disk Set Number | |
|---|---|---|
| | (or virtual track or RAID | Read/write |
| Platter Number | Set) | Mechanism |
| 0 | 1 | A |
| 1 | 2 | A |
| 2 | 3 | A |
| 3 | 4 | A |
| 4 | 1 | B |
| 5 | 2 | B |
| 6 | 3 | B |
| 7 | 4 | B |
| 8 | 1 | C |
| 9 | 2 | C |
| 10 | 3 | C |
| 11 | 4 | C |

Table 5 below illustrates an example of a four-read/write mechanism using a 12-platter cartridge:

TABLE 1
Disk Mapping in 4 Channel Unit

| | Logical Disk Set Number | |
|---|---|---|
| | (or virtual track or RAID | Read/write |
| Platter Number | Set) | Mechanism |
| 0 | 1 | A |
| 1 | 2 | A |
| 2 | 3 | A |
| 3 | 1 | B |
| 4 | 2 | B |
| 5 | 3 | B |
| 6 | 1 | C |
| 7 | 2 | C |
| 8 | 3 | C |
| 9 | 1 | D |
| 10 | 2 | D |
| 11 | 3 | D |

There are many other possible configurations of the general concept. Some examples are:

A cartridge that splits open to allow the drive mechanism to be inserted into the cartridge; instead of the platters being extracted from the cartridge outline, they are spun inside the outline, thus making the mechanism depth as short as possible. The cost to this approach is an increase in the required mechanism height and the cartridge complexity.

While standard 120 mm DVD RW platters are emphasized here, the concept can be implemented with CD-RW, Mini (80 mm) CD-RW, Mini (80 mm) DVD RW or ultra small form-factor such as DataPlay disks where size or cost constraints are a major consideration.

Next generation media such as second generation DVD (possibly >20 GB per disk) or holographic disks (possibly >40 GB per disk) may also be used as they become available. In this way the inventions disclosed here leverage the optical RW disk road map to provide its own road map of very high capacity, high reliability, high data rate cartridges.

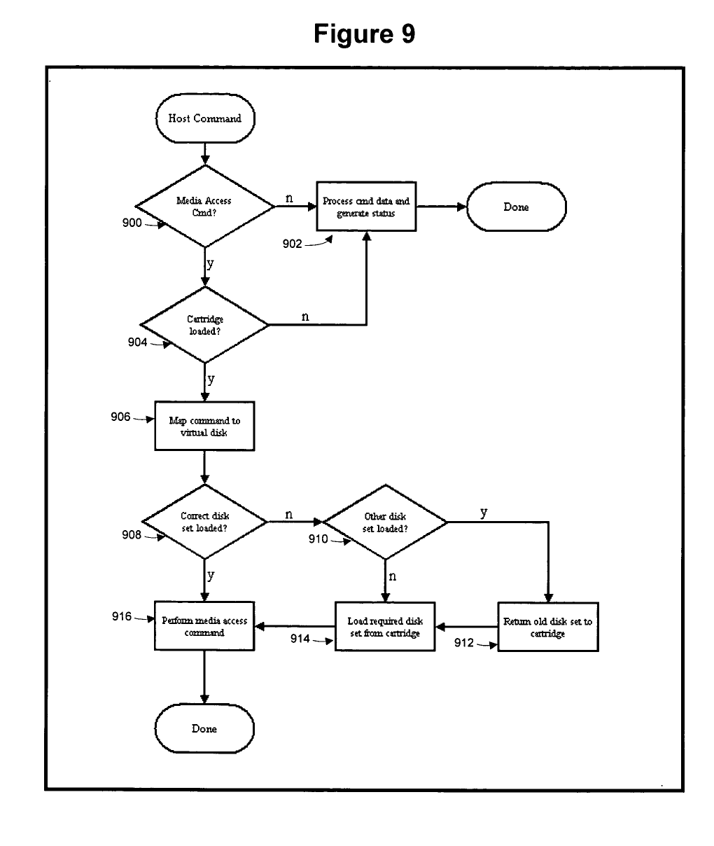

FIGS. 9 through 13 are flowcharts describing methods associated with features and aspects hereof to process host commands, emulate desired device types, read or write corresponding data and manipulate platters within the cartridge. FIG. 9 is a flowchart describing high level processing providing features and aspects hereof in response to receipt of a command from an attached host computer. Element 900 is first operable to determine whether the host command requires access to the cartridge media. If not, element 902 is operable to process the command and generate an appropriate response. Such commands may include simple status or other inquiry commands requiring no access to the cartridge media. If element 900 determines that the received command requires access to the cartridge media, element 904 is next operable to determine whether any cartridge is presently loaded in the system. If not, processing continues with element 902 to complete the command and return an appropriate status indicator. If a cartridge is presently loaded, element 906 is operable to map the received command of the emulated device to corresponding commands appropriate to media cartridge. For example, where streaming tape commands are received, element 906 maps the received commands and associated data to corresponding commands associated with one or more platters of the inserted cartridge. Element 906, in essence, implements the above identified virtualization engine features and aspects hereof. Following such mapping, element 908 is operable to determine whether the correct subset of platters from within the cartridge is presently engaged with the drive mechanism. If not, element 910 determines whether another platter subset is presently engaged with the drive mechanism. If so, element 912 is operable to manipulate the robotic extraction assemblies to return the presently loaded subset of platters to its appropriate position in the cartridge. Once the presently loaded subset is returned to the cartridge, or if element 910 determines that no subset is presently engaged with the drive mechanisms, element 914 is operable to manipulate the extraction and drive mechanisms to load the required subset of platters from the cartridge into the corresponding drive mechanisms. When the appropriate a set of platters has been loaded into the drive mechanism by operation of element 914, or if the proper subset is already loaded as determined by element 908, element 916 is next operable to perform the received media access command writing data to the loaded subset of platters or reading data from the loaded subset of platters.

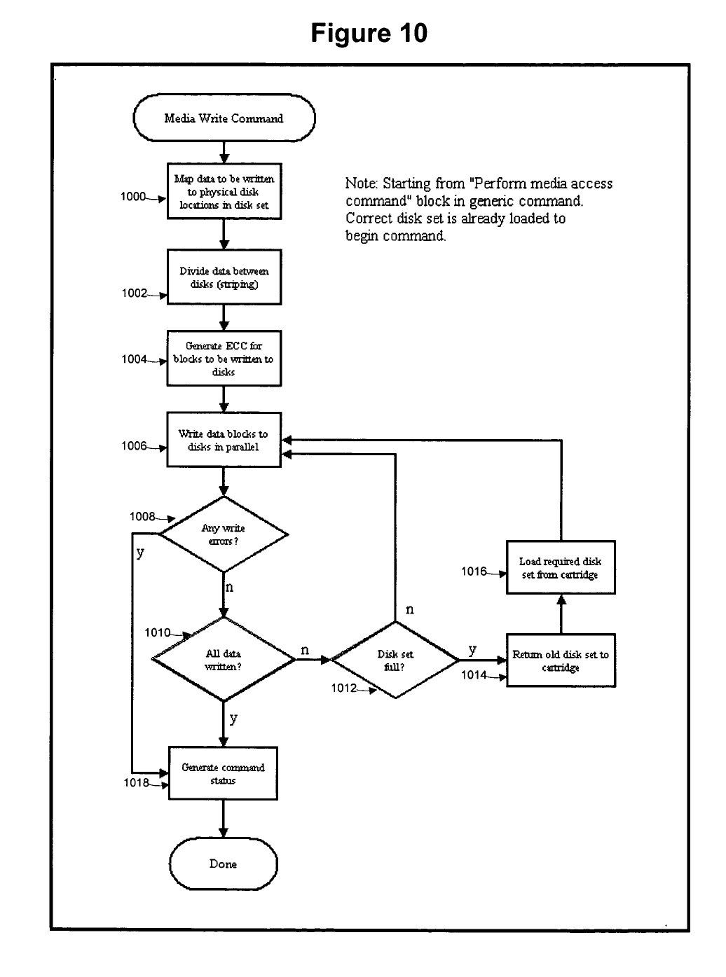

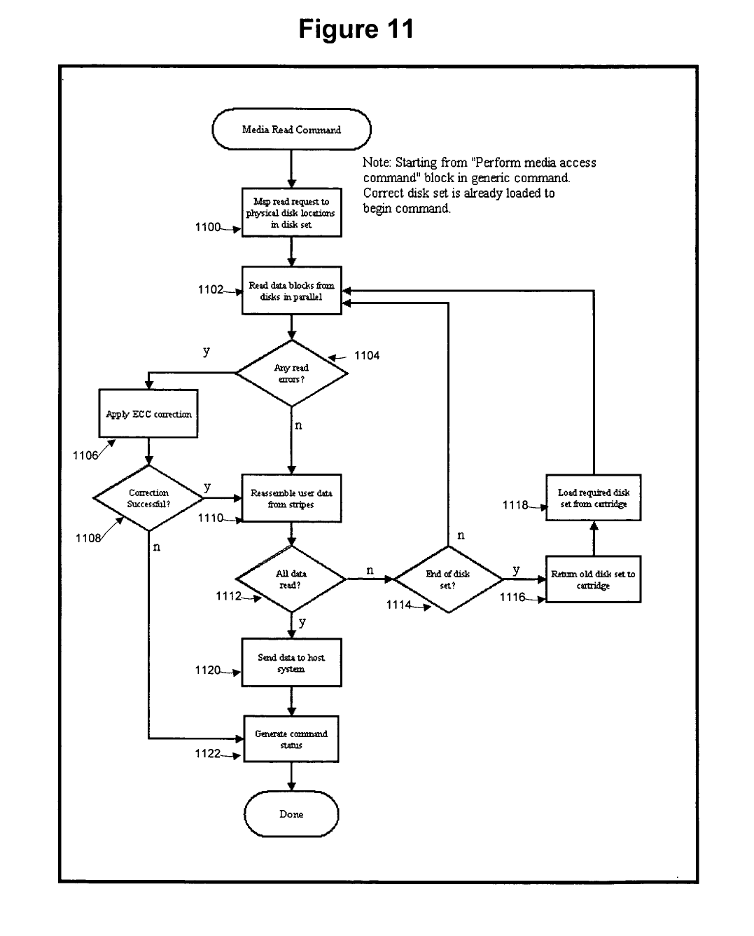

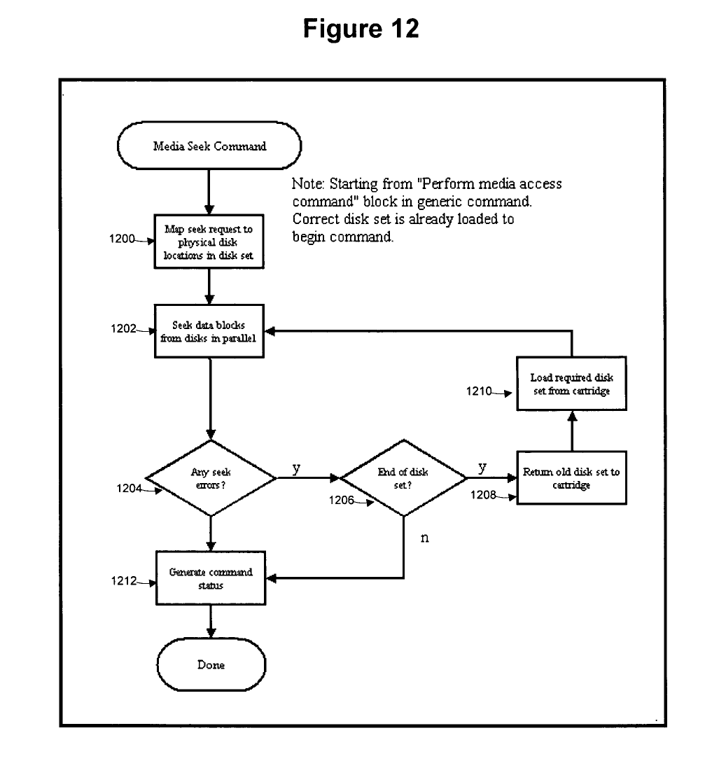

FIGS. 10 through 12 provide additional details of the processing of element 916 to perform a received media access command. FIG. 10 provides further detailed processing associated with performing a media write command. FIG. 11 provides similar detail corresponding to performance of a media read command. FIG. 12 provide similar detail to perform a media seek (position) command.

Element 1000 of FIG. 10 is operable to map the data to be written from provided logical addresses into corresponding physical locations in the presently loaded platter subset. Mapping such logical addresses to corresponding physical locations is performed in accordance with RAID or other storage management techniques applied within the system in accordance with features and aspects hereof. Further details of such mapping but are discussed herein below. Element 1002 then determines how the data is to be distributed over the various subsets of platters in the cartridge—i.e., striping of the supplied data is determined. Element 1004 is next operable to generate any required additional error correction code for the supplied data blocks to be written on to the presently loaded platter subset. Features and aspects hereof may provide additional error correcting features above and beyond those normally provided in digital data encoded on optical storage media. Element 1006 is next operable to write the provided data blocks plus any additional error correction or redundancy information generated above onto the presently loaded subset of platters. Where multiple platters are engaged with corresponding drive mechanisms, the multiple read/write assemblies may be operated in parallel to thereby enhance throughput for the write operation. Element 1008 then determines whether any write errors were detected in completing the write operations of element 1006. If so, processing terminates and element 1018 returns an appropriate error status. If not, element 1010 is operable to determine whether all data from the media write command has been processed. If so, element 1018 is operable to return a successful completion status to the requesting host system. If element 1010 determines that further data remains to be written, element 1012 is operable to determine whether the remaining data may be written on the presently loaded platter subset. If the present platter subset is not filled, processing continues with element 1006 to continue writing additional data to the presently loaded platter subset. If element 1012 determines that no further data can be written to the presently loaded platter subset, element 1014 is operable to manipulate the extraction and drive mechanisms to return the presently loaded platter subset to the cartridge and element 1016 manipulates the extraction and drive mechanisms to load the next platter subset from the cartridge into the drive mechanisms. Processing then continues with element 1006 to continue writing additional data to the newly loaded platter subset. Elements 1006 a through 1016 are therefore iteratively operable until all data supplied in the media write command has been successfully written to the cartridge platters or until an appropriate error response has been returned.

FIG. 11 provides additional detail regarding processing of a media read command. The method of FIG. 11 is similar to that expressed above with regard to FIG. 10 but rather reads requested data from the cartridge for return to the requesting host system. Element 1100 is operable to map the requested logical addresses to corresponding physical platter locations in the media cartridge. Element 1102 then performs read operations on the presently loaded platter subset at the mapped physical locations of the subset. Element 1104 next determines whether any read errors were detected in the read processing of element 1102. If so, element 1106 is operable to apply any error correction code or redundancy information read from the platter subset to attempt correction of the read errors. As known in the art, various error correcting codes as well as RAID redundancy information may be utilized to correct read errors in digital data. Element 1108 then determines whether the attempted correction was successful. If not, processing completes and element 1122 returns an appropriate error status to the requesting host system. If error correction was successful or if no errors are detected by element 1104, element 1110 is operable to reassemble the read data from its striped format into sequential format appropriate for the read operation being performed (assuming striping was applied to the data written on the platter subset). Element 1112 then determines whether all requested data has been successfully read. If so, element 1120 and 1122 are operable to return the requested data to the host system and to return an appropriate successful completion status. If element 1112 determines that additional data remains to be read, element 114 is operable to determine whether all possible data has been read from the presently loaded platter subset. If not, processing continues looping back to element 1102 to continue reading additional data from the presently loaded platter subset. Element 1116 is operable to return the presently loaded platter subset to the cartridge and element 1118 loads a next platter subset into the drive mechanism. Processing then continues looping back to element 1102 to continue reading data from the newly loaded platter subset. Element 1102 through 1118 are therefore interactively operable until all data requested has been read from a storage cartridge.

FIG. 12 describes processing of a media seek command often utilized in tape device controls for purposes of positioning the tape to an appropriate file position. Element 1200 is operable to map the requested tape location to a corresponding physical location in the platters of the media cartridge. Element 1202 then positions all drive mechanisms and their corresponding read/write assemblies to the appropriate starting position and the presently loaded platter subset. Element 1204 then determines if any errors arose in performing the seek operation of element 1202. If so, element 1206 determines whether the required seek position is beyond the extent of the presently loaded planner subset. If not, element 1212 completes processing and returns an appropriate error status to the requesting host a system. If so, element 1208 is operable to unload the presently loaded platters subset and element 1210 is operable to load a next platter subset from a storage cartridge. Processing then continues looping back to element 1202 until the appropriate position is located in the cartridge media.

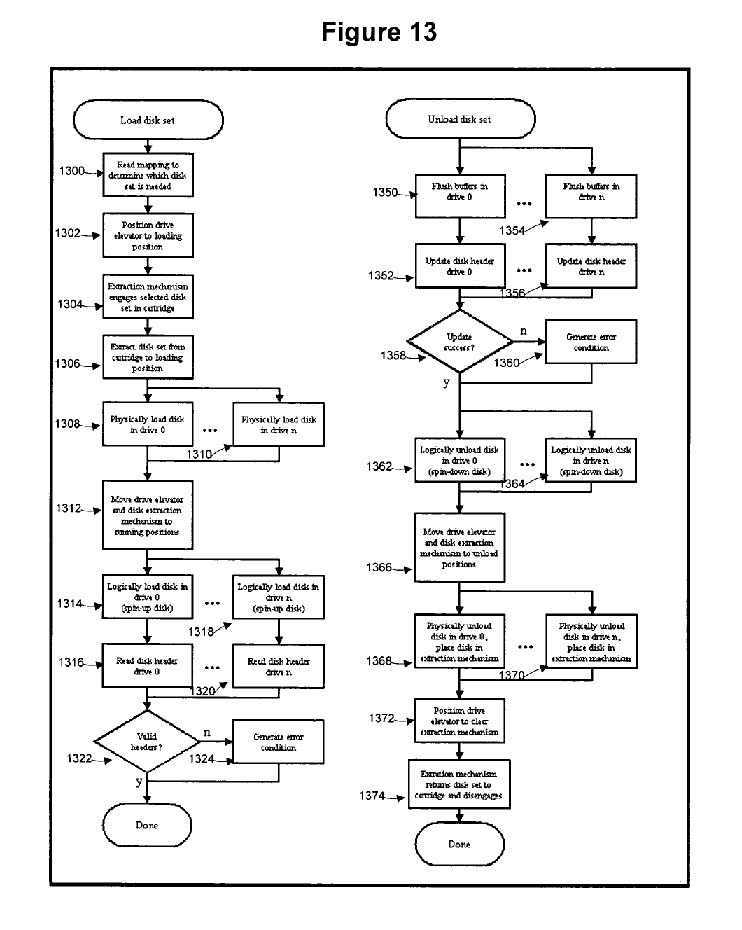

FIG. 13 provides flowcharts with additional information regarding loading or unloading of a platter subset from the inserted cartridge. Elements 1300 through 1324 provide details regarding loading of a platter subset. Elements 1350 through 1374 provide additional details regarding unloading of a presently loaded platter subset. Element 1300 is first operable to read mapping information to determine which platter subset is to be loaded. As noted herein, each platter within a cartridge may include header information useful for such mapping purposes. Element 1302 next positions the elevator assembly to an appropriate position for the identified platters in the subset to be loaded. Element 1304 next engages the extraction mechanism to select appropriate platters from the cartridge in accordance with the mapping information determined above. Element 1306 then extracts the appropriate platters from the cartridge and elements 1308 through 1310 physically engage the extracted platters with corresponding drive mechanisms. As indicated in FIG. 13 any number of such platters may be simultaneously engaged. Element 1312 then shifts the extraction mechanism to an appropriate position so as to not interfere with proper operation of the drive mechanisms during read and write operations. Elements 1314 and 1316 then logically load the platter engaged with a first drive mechanism and reads the header information from that platter. In like manner, elements 1318 and 1320 engage logically load a corresponding platter in another drive mechanism. As above, any number of a such platters and corresponding drive mechanisms may be logically loaded and corresponding headers read therefrom. Element 1322 then verifies that all the read headers indicate a valid media appropriately recorded and formatted in accordance with features and aspects hereof. If any errors were detected, element 1324 returns an appropriate errors status, otherwise, an appropriate successful status is returned.

Elements 1350 through 1374 provide corresponding detail for the unload processing associated with the presently loaded platter subset. Elements 1350 and 1352 are first operable to flush any buffers presently loaded for a first drive mechanism and element 1352 updates header information on the platter of a first drive mechanism. Elements 1354 and 1356 perform identical processing for another drive mechanism. As noted above, any number of a such drive mechanisms may be operable in parallel depending on the number of platters associated with a particular subset. Element 1358 then determines whether all headers were successfully updated. If not, an error condition may be later returned to the requesting host. Elements 1362 and 1364 then logically unload the platters from their corresponding multiple drive mechanisms. As noted, any number of drive mechanisms may be substantially simultaneously logically unloaded. Element 1366 then activates the elevator and extraction assemblies to position to an appropriate position for unloading platters presently loaded in the drive mechanisms. Elements 1368 and 1370 then substantially simultaneously physically unload the platters in each of the presently loaded drive mechanisms. Element 1372 then repositions the elevator and extraction mechanisms to an appropriate position for reinsertion of the unloaded platters into the media cartridge. Element 1374 then returns the unloaded platter subset into the cartridge and returns an appropriate status code to the requesting process.

Cartridge

The cartridge features and aspects hereof contain multiple optical media platters densely stacked to provide enhanced storage capacity as compared to a single storage platter. Though densely packed, the multiple platters may be separated physically to substantially preclude physical contact between platter and thereby reduce scratching of the data recording surfaces.

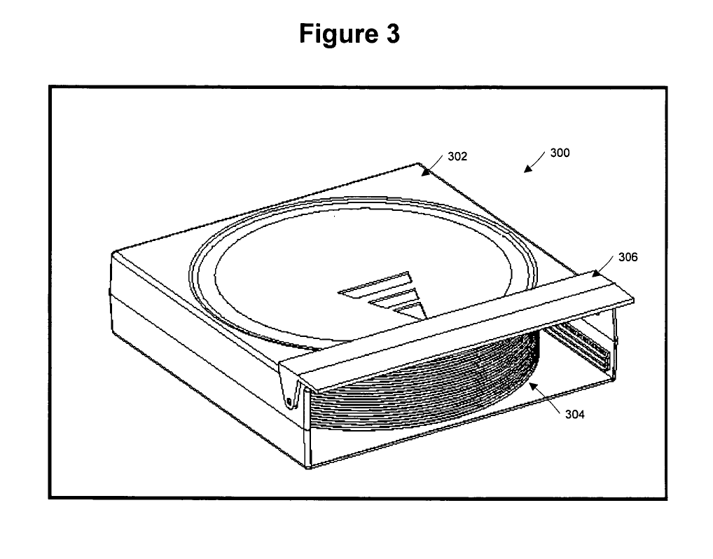

In one embodiment, the cartridge includes multiple slidable trays each adapted to receive a single media platter. FIG. 3 shows an exemplary cartridge 300 having a housing 302 containing multiple platters 304. A hinged door 306 is normally closed and shown in an open position in FIG. 3 to permit access to the multiple media 304 within the housing 302 of the cartridge 300. The door 306 and housing 302 are coupled with a lock mechanism (not shown) as generally known in the art to substantially preclude user access to the media to thereby reduce possibility of damage or contamination of the media by human contact. Such a lock mechanism is generally known to those of ordinary skill in the art. The lock (not shown) is engaged by elements of the system to unlock the door and to open the door (as shown in FIG. 3) when the cartridge is inserted into the system.

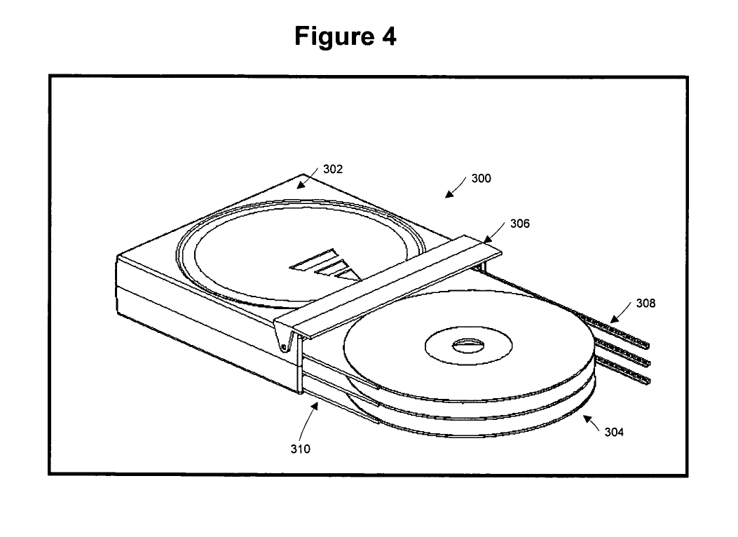

Within housing 302 are multiple trays, each adapted to receive a single platter. FIG. 4 shows cartridge 300 with door 306 open and three trays 310 extracted from the cartridge. Each tray 310 is holding a single platter 304. One edge of each tray 310 is adapted to provide a rack 308 that may be engaged with a pinion gear (not shown) of the system. The rack 308 may therefore be used by appropriate robotic manipulation of an extraction assembly to extract one or more trays 310 with platters 304 from the cartridges 300.

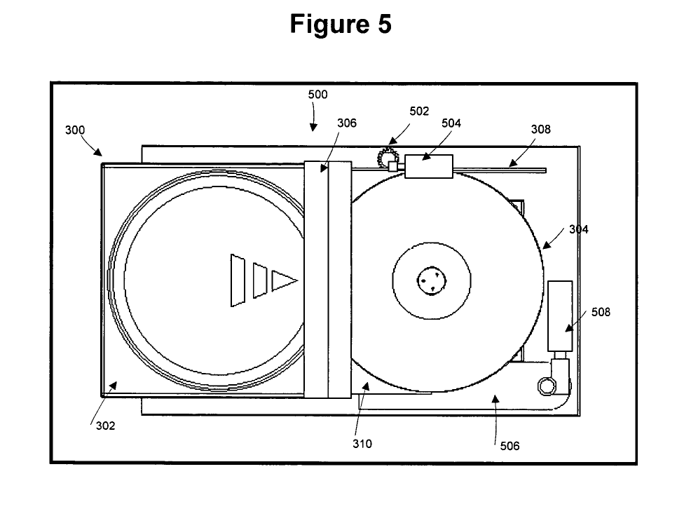

FIG. 5 shows a top view of cartridge 300 as inserted into system 500. By insertion into system 500, door 306 is unlocked and opened via well known mechanical linkages or other means (not shown). An extraction assembly may include pinion gear 502 driven by motor 504 engaged with rack 308 of each tray 310 to be extracted from housing 302. Well known servo and other control means integrated with the system (e.g., with the controller of FIG. 1) may be used to actuate and control motor 504 and hence extraction of one or more trays 310 with platters 304.

When so extracted from the cartridge 300, extracted platters 304 are engaged with a read/write assembly including read/write heads 506. One or more such read/write heads 506 may be vertically aligned with the extracted platters 304 by an elevator assembly that includes a screw drive assembly 508. The extraction motor and pinion and read/write assemblies may be integrated such that the elevator control of screw drive 508 may align the requisite motors and gears for both extraction and for engaging of the read/write heads with the extracted platters 304.

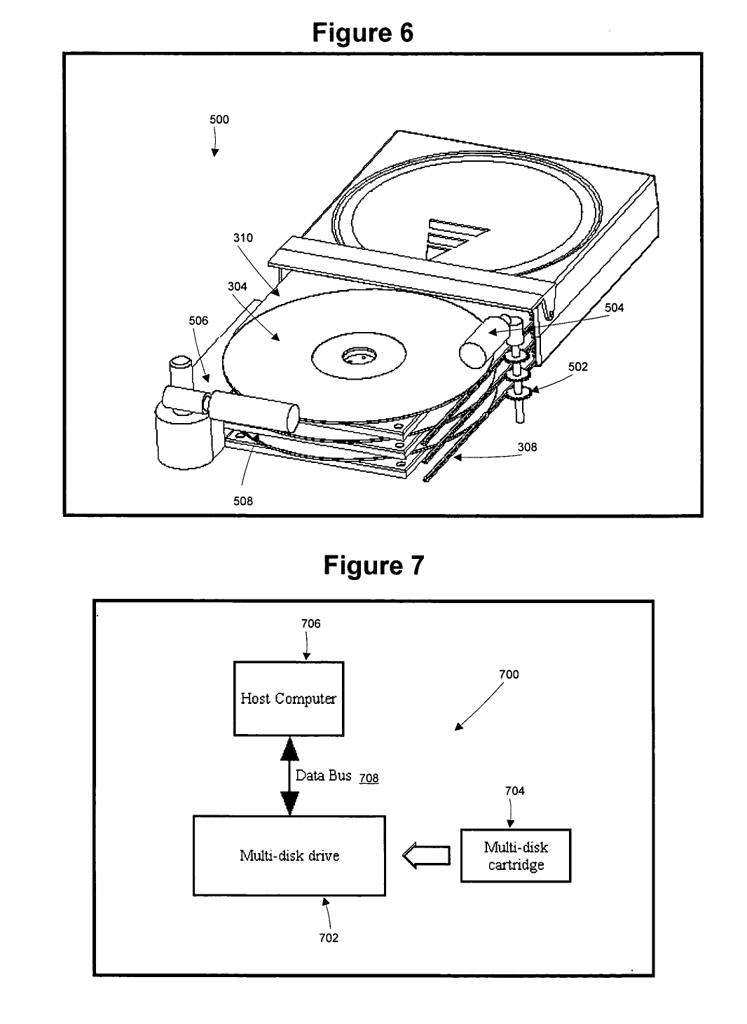

FIG. 6 provides another view of the system 500 better showing the extraction of multiple (three) platters 304 by multiple pinion gears 502 engaging multiple racks 308 of multiple trays 310. Motor 504 therefore extracts a subset of multiple platters 304 for engaging with corresponding multiple read/write assemblies 506.

Details of such robotic manipulation and control to extract trays and platters from the cartridge and to align extracted platters with read/write assemblies are generally known and exemplified by the above-identified, incorporated US patent references.

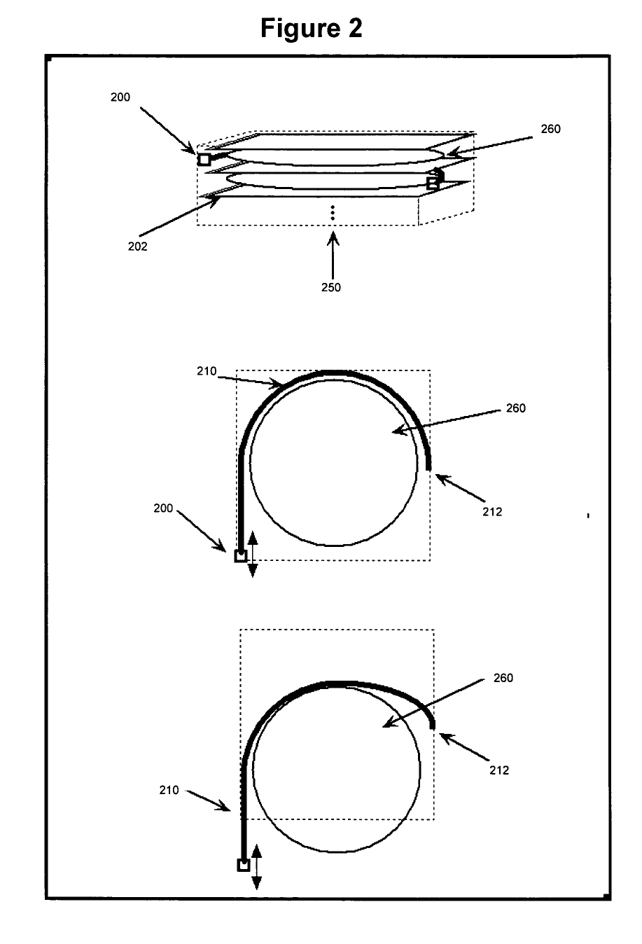

FIG. 2 depicts multiple views of an alternative embodiment for extraction of the platters 260 from a cartridge 250. A flexible band 210 has a tab 200 that may be gripped by a suitable robotic gripper mechanism (not shown). The opposite end of the band 210 is anchored to the cartridge 250 at anchor point 212. When a robotic gripper/manipulator grips tab 200 and pulls it away from the cartridge 250, the platter 260 that is encompassed by the band 210 is extracted from the cartridge 250. When the platter 260 is to be re-inserted in the cartridge 250, a suitable robotic manipulator (not show) pushes the platter back into the cartridge thus moving band 210 to its nominal position behind the corresponding platter. Multiple such bands 210, each surrounding the rear of a corresponding platter 260 may be positioned within the cartridge 250 to provide for extraction of multiple platters or individual platters. A suitable manipulator (not shown) may therefore extract a single platter from the cartridge 250 or, by gripping multiple tabs 200, extract a selected subset of multiple platters 260 from cartridge 250. As above, suitable robotic grippers and manipulators are generally known in the art as exemplified by the incorporated, above-identified patents.

Logical Format

In order to record on multiple disks and support the possibility of both streaming (tape) and random access media (CD/DVD/HD) device models, a logical format must be implemented. A logical format is also provided to map the various block sizes and compressed data sizes into the physical record sizes of the striping. The logical format is a higher level of data organization that describes and contains the user data before being recorded into the physical data blocks that are the unit of recording on the disks.

Each disk contains a header near the beginning of the recordable area. The header identifies information for the controller to verify that the proper disk has been loaded and to aid in accessing the user data recorded on the disk. A typical disk header will include the following information at a minimum (the size of individual fields may be from a single bit to several bytes):

TABLE 1
Example Disk Header

| Field | Description |
|---|---|
| Cartridge Serial Number | a worldwide unique identifier for |
| | the entire cartridge |
| Cartridge Disk Number | a number identifying the disk |
| | position in the cartridge (i.e. 0 |
| | through 11 for a 12 disk cartridge) |
| Redundancy Level | an identifier to signify the number |
| | of disks in each set, the redundancy |
| | contained in the ECC, and the |
| | striping method used |
| Disk Set Number | a number identifying which disk set |
| | within the cartridge this disk |
| | belongs to |
| Disk Set Element Number | a number identifying which disk |
| | this is within the disk set |
| Device Emulation Type | an indicator specifying which |
| | device type is being emulated (i.e. |
| | CD, DVD, tape, etc.) |
| First Logical Block Number On | the logical block number of the first |
| This Disk | user data address located on the disk |
| First Logical Block Physical | the physical block number mapping |
| Address | of the first user data located on the |
| | disk |
| Last Logical Block Number On | the logical block number of the last |
| This Disk | user data address located on the disk |
| Last Logical Block Physical | the physical block number mapping |
| Address | of the last user data located on the |
| | disk |
| Table of Contents Address | a physical address for TOC when |
| | emulating CD formats |
| Overwrite Counter | streaming data current overwrite |
| | counter (see block header below) |

A directory header can also exist near the mount point of each disk. The directory will contain seek tables which can accelerate the mapping of user data to physical locations for fast access to requested data. The directory can also contain log data to enable tracking the read and write reliability of the individual platters over the lifetime of the cartridge. When any component of the cartridge begins to show indications of diminished reliability, the drive mechanism will be able to assess the risk and report the degradation to the host computer.

Each logical data block or group of logical data blocks may contain a header defining the logical contents. Physical blocks are fixed size, dictated by the physical block size on the recording medium and the number of stripes being used. A typical header contains the following fields at a minimum (the size of individual fields may be from a single bit to several bytes):

TABLE 2
Example Block Header

| Field | Description |
|---|---|
| Physical Block Number | a sequential position counter |
| | starting from the beginning of each |
| | piece of media |
| Logical Block Number | the position number as understood |
| | by the host computer applications, |
| | each logical block number |
| | identifying a unique block of data, |
| | filemark, or setmark as generated by |
| | the host computer applications |
| Logical Block Control Flags | a logical block may be bigger or |
| (Block Start, Block End) | smaller than a physical block. In |
| | order to track when spanning |
| | several physical blocks with a single |
| | logical block, or to deal with several |
| | logical blocks packed into a single |
| | physical block, a series of control |
| | flags are maintained |
| Block Type | identifies streaming data, |
| | compressed streaming data, |
| | filemark, setmark, end-of-data |
| | (EOD), padding, or uncompressed |
| | random access data |
| Logical Block Count | the number of logical block starts |
| | contained in this physical block |
| Logical Block User Size | the uncompressed block size as sent |
| | by the host application |
| Logical Block Compressed Size | the actual size of the user data block |
| | that is recorded on the media after |
| | compression |
| Overwrite Counter | when recording streaming data, a |
| | physical block may be skipped due |
| | to a write error or due to |
| | performance (data padding). A |
| | subsequent read may read old data |
| | from a previous write operation. An |
| | overwrite counter as used in many |
| | tape technologies allows a |
| | mechanism to determine if old |
| | irrelevant data is being read, |
| | allowing the controller to proceed to |
| | the next physical block in search of |
| | the desired logical data |

Additional control fields can be used to improve seek times, such as linked lists to other data blocks or media markers (such as filemarks, setmarks, re-mapped blocks, or end-of-data).

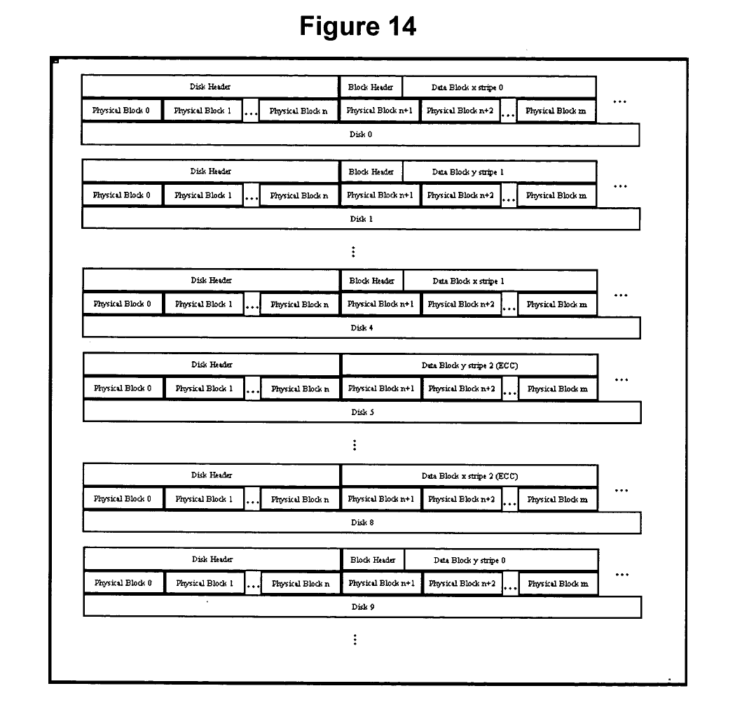

FIG. 14 is a block diagram showing distribution of data over a plurality of media platters in a cartridge using RAID level 5 striping incorporating parity (or ECC) redundancy information. FIG. 14 shows data interleaving for an exemplary 3-drive 12-platter system with high error correction capability. As shown, logical data may be interleaved and striped. Disks 0, 4, and 8 are part of one disk set; disks 1, 5, and 9 are part of another. Logical blocks are recorded across several physical blocks. All of the user data is split between stripe 0 and stripe 1. Data integrity is improved by creating a 3^{rd} redundancy information stripe of Reed-Solomon (or simple XOR parity or similar ECC block) for each logical block and recording it on a third disk in the set, the ECC having sufficient redundancy to correct for a complete failure of one of the disk mechanisms or platters.

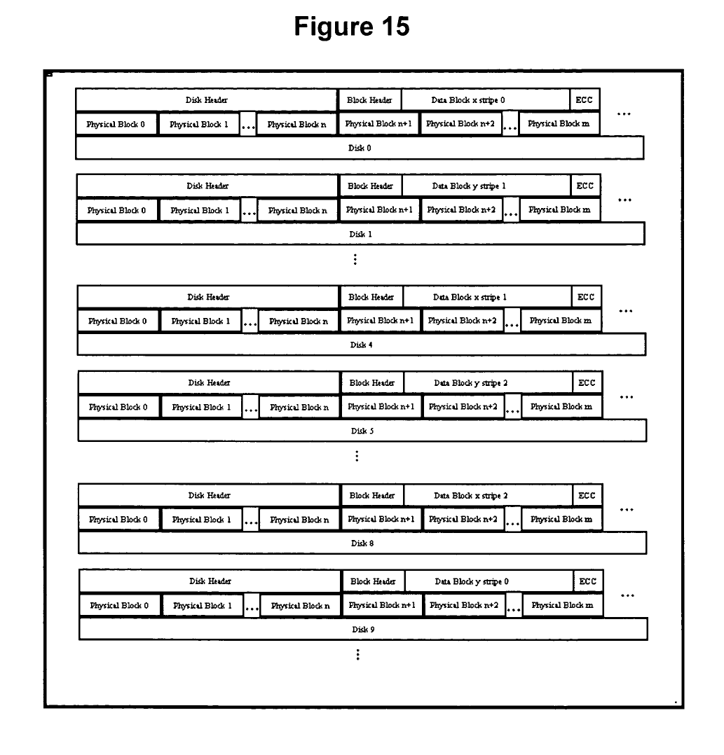

FIG. 15 shows data interleaving for an exemplary 3-drive 12-platter system with high data rate and capacity. FIG. 15 shows an example of how the logical data may be interleaved and striped. Disks 0, 4, and 8 are part of one disk set; disks 1, 5, and 9 are part of another. Logical blocks are recorded across several physical blocks. Data integrity is improved by appending a Reed-Solomon or similar ECC code portion to each logical block, the ECC having sufficient redundancy to correct for 1 or more physical blocks that are unreadable.

What is claimed is:

1. An optical data storage system comprising:
a plurality of optical media platters; and
a cartridge housing the plurality of optical media platters wherein the plurality of optical media platters are pre-loaded in the cartridge and wherein the cartridge is adapted to substantially preclude user access to the plurality of optical media platters.

2. The system of claim 1 wherein each platter of the plurality of optical media platters is a rewritable media.

3. The system of claim 1 wherein each platter of the plurality of optical media platters is a write-once media.

4. The system of claim 1 wherein the cartridge further comprises:
a plurality of sliding trays each adapted to receive a corresponding platter of the plurality of optical media platters and further adapted to permit slidable extraction of the corresponding platter from the cartridge.

5. The system of claim 1 wherein the cartridge further comprises:
a plurality of separators adapted as a bearing surface between individual platters of the plurality of optical media platters; and
a plurality of extractors each adapted to pull a corresponding individual platter of the plurality of optical media platters from the cartridge.

6. The system of claim 1 wherein the cartridge housing comprises an optically opaque material.

7. The system of claim 6 wherein the opaque housing is opaque to ultraviolet wavelengths.

8. The system of claim 1 further comprising:
a robotic assembly adapted to extract from the cartridge a subset of platters of the plurality of optical media platters and to return the extracted subset to the cartridge; and
a drive mechanism adapted for writing data on the subset and adapted for reading data from the subset.

9. The system of claim 8 wherein the system is operable to write redundancy information on the subset and is further operable to read the redundancy information in read operations to enhance reliability of the system.

10. The system of claim 8
wherein the drive mechanism further comprises:
an optical read/write assembly; and
a platter rotation assembly system, and
wherein the robotic assembly further comprises:
a positioning assembly to vertically align the optical read/write assembly and platter rotation assembly with the subset.

11. The system of claim 8 further comprising:
a cartridge opening mechanism to open the cartridge in response to insertion of the cartridge into the drive mechanism and to close the cartridge in association with extraction of the cartridge from the drive mechanism.

12. The system of claim 8 wherein the robotic assembly is adapted to fully extract the subset from the cartridge.

13. The system of claim 8 wherein the robotic assembly is adapted to partially extract the subset from the cartridge to an extent sufficient to engage the drive mechanism.

14. The system of claim 8 wherein the drive mechanism further comprises:
a storage controller including a host system interface and adapted to present the plurality of optical media platters as a contiguous storage volume to an attached host system.

15. The system of claim 14 wherein the controller is further adapted to present a streaming tape command set to an attached host computer.

16. The system of claim 15 wherein the controller is further adapted to record a volume header record at the beginning of the storage volume

17. The system of claim 15 wherein the storage volume comprises a plurality of logical blocks and wherein the controller is further adapted to record a block header at the beginning of each logical block.

18. The system of claim 15 wherein the storage volume comprises a plurality of logical blocks and wherein the controller is further adapted to record a block header at the beginning of each group of logical blocks of user data.

19. The system of claim 14 wherein the controller is further adapted to present a multi-media command set to an attached host computer.

20. The system of claim 14 wherein the controller is further adapted to provide data compression for data stored on the plurality of optical media platters and is further adapted to provide data decompression for data retrieved from the plurality media platters.

21. The system of claim 14 wherein the subset comprises multiple platters of the plurality of optical media platters and wherein the controller is further adapted to distribute data over the subset.

22. The system of claim 14 wherein the read/write assembly comprises a plurality of read/write heads and wherein the controller is further adapted to stripe data over the subset using the plurality of read/write heads substantially in parallel.

23. The system of claim 14 wherein the controller is further adapted to record a header record on each platter of the plurality of optical media platters wherein the header identifies a cartridge relative index of the corresponding platter indicative of the corresponding platter's position within the cartridge.

24. The system of claim 23 wherein the header further identifies a subset membership index of the corresponding platter indicative of which subset of a plurality of subsets of the cartridge in which the corresponding platter is a member.

25. The system of claim 24 wherein the header further identifies a subset relative index of the corresponding platter indicative of the corresponding platter's position within the subset.
